(19) United States
(12) Patent Application Publication
(10) Pub. No.: US 2025/0133747 A1
(43) Pub. Date: Apr. 24, 2025

(54) METHOD FOR FABRICATING A SELECTOR AND A SEMICONDUCTOR DEVICE INCLUDING THE SELECTOR

(71) Applicant: SK hynix Inc., Icheon-si (KR)

(72) Inventors: Jeong Myeong KIM, Icheon-si (KR); Cha Deok DONG, Icheon-si (KR); Keo Rock CHOI, Icheon-si (KR)

(21) Appl. No.: 18/752,597

(22) Filed: Jun. 24, 2024

(30) Foreign Application Priority Data
Oct. 20, 2023 (KR) 10-2023-0141542

(51) Int. Cl. H10B 61/00

(52) U.S. Cl. CPC H10B 61/10

(57) ABSTRACT

A selector includes a carbon material that includes carbon and a trivalent element that is chemically bond to cardon; and a dopant material implanted to the carbon material to form trap sites of conductive carriers based on a chemical bond between the carbon and the trivalent element in the carbon. A method for fabricating a selector includes forming a carbon layer that includes carbon; chemically reacting a trivalent element with the carbon in the carbon layer; and implanting a dopant through an ion implantation process.

### PRIORITY CLAIM AND CROSS-REFERENCE TO RELATED APPLICATIONS

The present application claims priority under 35 U.S.C. 119 (a) to Korean Patent Application No. 10-2023-0141542, filed on Oct. 20, 2023, in the Korean Intellectual Property Office, which is incorporated herein by reference in its entirety.

### TECHNICAL FIELD

Embodiments of the present disclosure relate to a memory circuit or a device, and their applications to a semiconductor device.

### BACKGROUND

Recent demands for miniaturization, low power consumption, high performance, and diversification of electronic devices require semiconductor devices capable of storing information in various electronic devices, such as computers and portable communication devices, and researchers and the industry are studying to develop such semiconductor devices. Among the semiconductor devices are those that may store data by taking advantage of the characteristic of switching between different resistance states according to the applied voltage or current, such as a Resistive Random Access Memory (RRAM), a Phase-change Random Access Memory (PRAM), a Ferroelectric Random Access Memory (FRAM), a Magnetic Random Access Memory (MRAM), an E-fuse and the like.

### SUMMARY

Embodiments of the present disclosure are directed to a selector with excellent electrical and physical characteristics by using carbon as a matrix of the selector, chemically reacting the carbon with a trivalent element, and then ion-implanting a dopant, a semiconductor device including the selector, and a method for fabricating the semiconductor device.

In accordance with an embodiment of the present disclosure, a selector includes: a carbon material that includes carbon and a trivalent element that is chemically bond to cardon; and a dopant material implanted to the carbon material to form trap sites of conductive carriers based on a chemical bond between the carbon and the trivalent element in the carbon material.

In accordance with another embodiment of the present disclosure, a method for fabricating a selector includes forming a carbon layer that includes carbon; chemically reacting a trivalent element with the carbon in the carbon layer to chemically bond the trivalent element and the carbon; and implanting a dopant through an ion implantation process.

In accordance with another embodiment of the present disclosure, a semiconductor device includes: a selector pattern that includes carbon, a trivalent element and a dopant that are chemically bonded via a chemical bond among the carbon, the trivalent element, and the dopant; and a memory pattern coupled to the selector pattern.

In accordance with another embodiment of the present disclosure, a method for fabricating a semiconductor device includes: forming a carbon layer containing carbon; performing a chemical reaction between a trivalent element and the carbon in the carbon layer; subsequently implanting a dopant into the carbon layer through an ion implantation process; forming a memory layer that is couple to the selector layer; and subsequently etching the memory layer and the selector layer using a mask pattern to form a memory pattern from the memory layer and a selector pattern from the carbon layer with the chemically bonded carbon, trivalent element and the dopant to form a memory cell including the memory pattern and a selector pattern.

### BRIEF DESCRIPTION OF THE DRAWINGS

FIGS. 1A to 1C illustrate a method for fabricating a selector in accordance with an embodiment of the present disclosure.

FIGS. 2A and 2B illustrate a semiconductor device in accordance with an embodiment of the present disclosure.

FIGS. 3A to 3G illustrate a method for fabricating a semiconductor device in accordance with an embodiment of the present disclosure.

FIGS. 4A to 4G illustrate a method for fabricating a semiconductor device in accordance with another embodiment of the present disclosure.

### DETAILED DESCRIPTION

Exemplary embodiments of the present disclosure will be described below in more detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout the disclosure, like reference numerals refer to like parts throughout the various figures and embodiments of the present disclosure.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

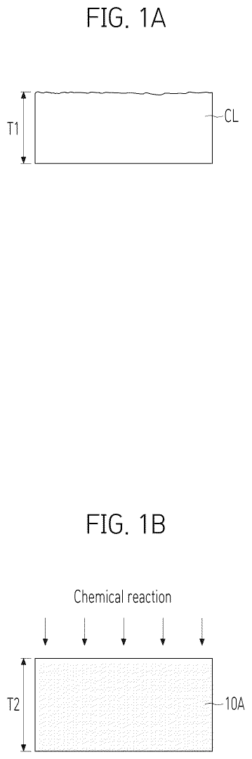

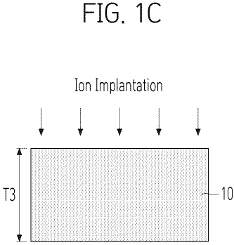

FIGS. 1A to 1C illustrate a method for fabricating a selector in accordance with an embodiment of the present disclosure.

In the embodiment of FIGS. 1A to 1C, a method for fabricating a selector is illustrated. The description below is focused on fabricating the selector and the description on the structures other than the selector disposed in upper and lower portions of the selector are omitted.

Referring to FIG. 1A, a carbon layer CL may be formed.

The carbon layer CL may serve as a matrix that forms the base of a selector. The carbon layer CL may be formed of or include an amorphous phase to readily involve in a chemical reaction, and when dopants such as arsenic (As) are ion implanted, new structural bonds may be easily formed, and the metallic states of the dopants may be maintained well. Therefore, the ion-implanted dopants may be able to form the trap sites of conductive carriers more easily and efficiently, thereby effectively realizing the threshold switching operation characteristics of the selector. As discussed later in this patent document, the selector has the thresholding switching by exhibiting two different electrical conducting states in response to an applied voltage and can exhibit, and selectively switch between, (1) an electrical conducting state to allow passage a current through the selector, and (2) an electrical non-conducting state that blocks the passage of the current through the selector, depending on whether the applied voltage is above or below a threshold voltage. Since the carbon layer CL has low density and high thermal conductivity, the selector based on the carbon layer CL may have excellent electrical and physical characteristics.

The carbon layer CL may be formed by depositing carbon (C) using a physical deposition method e.g., a sputtering method.

According to one embodiment of the present disclosure, the carbon layer CL may include carbon (C) atoms and further include at least one of nitrogen (N) atoms, oxygen (O) atoms, or hydrogen (H) atoms. For example, the carbon layer CL may include carbon (C) atoms as a main component and further include nitrogen (N) atoms, oxygen (O) atoms, or hydrogen (H) atoms as sub-components. For example, the carbon layer CL may include carbon (C) atoms as the main component and further include any two of nitrogen (N) atoms, oxygen (O) atoms, or hydrogen (H) atoms as the sub-components. For example, the carbon layer CL may include carbon (C) atoms as the main component and further include nitrogen (N) atoms, oxygen (O) atoms, and hydrogen (H) atoms as the sub-components. In the embodiment, at least one of nitrogen (N) atoms, oxygen (O) atoms, or hydrogen (H) atoms may be doped into the carbon layer CL by performing a carbon (C) deposition process in a gas atmosphere of at least one of nitrogen gas, oxygen gas, or hydrogen gas.

The carbon layer CL may be formed to have a first thickness T1.

Referring to FIG. 1B, a chemical reaction may be performed onto the carbon layer CL to convert or modify the carbon layer CL into a chemical reaction layer 10A.

The chemical reaction shown in FIG. 1B refers to chemically reacting a trivalent element with the surface of the carbon layer CL. The trivalent element is placed into the carbon layer CL via chemical reaction with the element included in the carbon layer CL by using a plasma doing or other processing to include desired chemical reactions without using a direct ion implantation process to implant the trivalent element into the carbon layer CL. If the direct ion implantation process is used to implant the trivalent element into the carbon layer CL, ions of the trivalent element may be implanted into the inside of the carbon layer CL by bombarding the carbon layer CL, but the implanted ions may not chemically react with the components included in the carbon layer CL to form new structural bonds. Thus, in various implementations, it may be desirable to placing the trivalent element into the carbon layer CL via chemical reactions. According to the embodiment of the present disclosure, the chemical reaction shown in FIG. 1B can form the chemical reaction layer 10A which includes a complex chemical bond between the components included in the carbon layer CL and the trivalent element. As described above, the carbon layer CL may include carbon (C) atoms, and may optionally further include at least one of nitrogen (N) atoms, oxygen (O) atoms, or hydrogen (H) atoms. Accordingly, the chemical reaction layer 10A may include carbon (C) as the main component and may include the complex chemical bond that is formed through a chemical reaction with the trivalent element. Thus, the chemical reaction layer 10A may include a chemical bond between the carbon (C) and the trivalent element that is formed by the chemical reaction, and may optionally include a chemical bond between at least one of nitrogen (N), oxygen (O), or hydrogen (H) with the trivalent element in addition to the chemical bond between the carbon (C) and the trivalent element.

The trivalent element may refer to an element with three valence electrons. Here, the valence electrons refer to electrons that may participate in a chemical bond while the outer shell is not closed among the outer shell electrons of an atom. The trivalent element may be able to control off-current characteristics by chemically reacting with the element included in the carbon layer CL to form a chemical bond and trapping some of the conductive carriers through a hole that is formed due to a trivalent structure to prevent excessive current.

The trivalent element capable of chemically reacting with the element included in the carbon layer CL may include at least one of boron (B), aluminum (Al), gallium (Ga), indium (In), or thallium (Tl).

According to one embodiment of the present disclosure, when the trivalent element includes boron (B), the chemical reaction layer 10A may include a complex chemical bond formed of carbon (C), nitrogen (N), oxygen (O), hydrogen (H), or boron (B), for example, the chemical reaction layer 10A may include at least one of a B—C bond, a B—N bond, or a B—O bond.

The chemical reaction between the element included in the carbon layer CL and the trivalent element may be a plasma chemical reaction. The plasma chemical reaction may include a plasma doping (PLAD) process. When the trivalent element is chemically reacted with the carbon layer CL through the PLAD process, the trivalent element may chemically react with the elements including the carbon (C) on the surface of and inside the carbon layer CL to form new chemical bonds, converting or modifying the carbon layer CL into the chemical reaction layer 10A having a different structure and composition from those of the carbon layer CL.

According to one embodiment of the present disclosure, the chemical reaction between the element included in the carbon layer CL and the trivalent element may be performed through the PLAD process under the conditions of energy of approximately 1 to 5 KV and a trivalent element implantation amount of approximately 2.5×10¹⁵ cm⁻² to 2.5×10¹⁶ cm⁻². When the trivalent element implantation amount is out of the above range, the flexibility of carbon that forms the base of the selector may be decreased. As a result, it may be difficult to secure stable physical characteristics of the selector.

According to one embodiment of the present disclosure, when the trivalent element includes boron (B), the PLAD process may be performed using B₂H₆ or BF₃ plasma under the conditions of energy of approximately 1 to 5 KV and the trivalent element implantation amount of approximately 2.5×10¹⁵ cm⁻² to 2.5×10¹⁶ cm⁻². Hydrogen (H) included in the B₂H₆ or BF₃ plasma used in the PLAD process may form a chemical bond in the chemical reaction layer 10A.

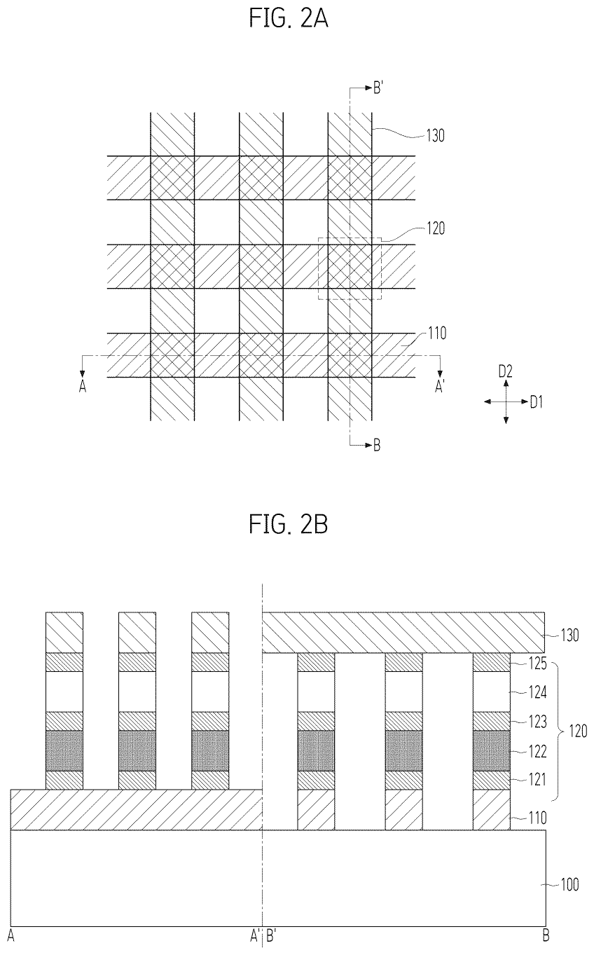

Since the chemical reaction layer 10A includes the chemical bond that is formed by the chemical reaction, a second thickness T2 of the chemical reaction layer 10A may be greater than the first thickness T1 of the carbon layer CL. This increase in the thickness may have a positive effect in securing stable physical characteristics of the selector that is formed finally. To be specific, during a dopant ion implantation process, which is a subsequent process in the formation of the selector, the chemical reaction layer 10A may be damaged inevitably from the ion implantation process. The chemical reaction layer 10A may have to secure the minimum thickness in order to function as a selector even though the chemical reaction layer 10A is damaged. According to this embodiment of the present disclosure, the second thickness T2 of the chemical reaction layer 10A may be greater than the first thickness T1 of the carbon layer CL before the conversion due to the chemical reaction with the trivalent element shown in FIG. 2B. Therefore, despite the damage caused by the subsequent ion implantation process, it is possible to secure stable physical characteristics of the selector that is formed finally.

In some implementations, the surface roughness characteristics of the chemical reaction layer 10A may be improved due to the chemical reaction between the element included in the carbon layer CL and the trivalent element. Since the carbon layer CL is deposited by a PVD (physical vapor deposition) method, such as a sputtering method, the surface roughness of the carbon layer CL may be poor. As the surface roughness of the chemical reaction layer 10A is reduced sufficiently due to the complex chemical bond that is formed through the chemical reaction with the trivalent element, the chemical reaction layer 10A may have a flat surface.

In some implementations, the chemical reaction layer 10A may exhibit improved density and flexibility compared to the carbon layer CL due to the newly formed complex chemical bonds. Therefore, the physical characteristics of the selector may be improved.

Referring to FIG. 1C, the selector 10 may be formed by implanting dopants into the chemical reaction layer 10A.

The dopants may form trap sites of conductive carriers, allowing the selector 10 to perform a threshold switching operation.

The dopants may include, for example, at least one of arsenic (As), phosphorus (P), or antimony (Sb). For example, the dopants may include arsenic (As), phosphorus (P), or antimony (Sb). For example, the dopants may include any two of arsenic (As), phosphorus (P), or antimony (Sb). For example, the dopants may include arsenic (As), phosphorus (P), or antimony (Sb).

According to one embodiment of the present disclosure, the dopants may be implanted through an ion implantation process.

The selector 10 may be formed to have a third thickness T3. According to one embodiment of the present disclosure, the third thickness T3 of the selector 10 may be the same as the second thickness T2 of the chemical reaction layer 10A. According to another embodiment of the present disclosure, the third thickness T3 of the selector 10 may be smaller than the second thickness T2 of the chemical reaction layer 10A. This is because a portion of the upper portion of the chemical reaction layer 10A may be lost due to the damage that may occur during the ion implantation process.

The selector 10 according to the embodiment of the present disclosure, which is formed according to the above-described method, may include amorphous carbon (C), which is the main component, and dopants, which are implanted through the ion implantation process, and the selector 10 may include a complex chemical bond which is formed by the chemical reaction between the carbon (C) and the trivalent element. Also, the selector 10 may optionally further include a chemical bond between at least one of nitrogen (N), oxygen (O), or hydrogen (H) and a trivalent element, in addition to the chemical bond between the carbon (C) and the trivalent element. The trivalent element may include at least one of boron (B), aluminum (Al), gallium (Ga), indium (In), or thallium (Tl), and the dopants may include at least one of arsenic (As), phosphorus (P), or antimony (Sb).

Unlike the conventional doped nitride or oxide-based selectors, the selector 10 according to the embodiment of the present disclosure may include carbon (C) of an amorphous phase, which may easily involve in a chemical reaction, as the main component, and may form a complex structural bond through a chemical reaction between carbon (C) which is a tetravalent element, thereby forming defects or vacancies in the selector 10. Accordingly, the metallic states of the dopants may be maintained well, which makes it possible to form trap sites of conductive carriers more easily and efficiently. This may further improve the electrical characteristics of the selector 10. Also, the off-current characteristics may be controlled as the trivalent element, which is chemically reacted with carbon, traps some of the conductive carriers so as to prevent excessive current. Also, the physical characteristics of the selector 10 may be improved due to the essential characteristics of carbon, which is the main component. In some implementations, when the selector 10 further includes at least one of nitrogen (N), oxygen (O), or hydrogen (H) in addition to carbon (C), more complex structural bonds may be formed due to the chemical reaction between the additional element and the trivalent element, which may further increase the extent of forming defects or vacancies in the selector 10. Thus, the defects or vacancies in the selector 10, which help to form trap sites of conductive carriers, can increase by including the additional element, at least one of nitrogen (N), oxygen (O), or hydrogen (H) in addition to carbon (C). Therefore, it is possible to control the extent of the structural bond due to a chemical reaction in the selector 10 by comprehensively considering the physical and electrical characteristics required for the target selector 10.

The selector 10 according to the embodiment of the present disclosure is formed by using a chemical reaction of the carbon with the trivalent element and can have improved thickness, density, and flexibility compared to the case of the carbon layer CL that is used a starting material without the chemical reaction. In the implementations the selector 10 can have reduced surface roughness, thereby exhibiting excellent electrical and physical characteristics.

The selector 10 according to the embodiment of the present disclosure may be a current adjustment layer which is capable of controlling the flow of current, and may reduce and/or suppress leakage current between the memory elements of a semiconductor device. The selector 10 may have threshold switching characteristics by exhibiting two different electrical conducting states: a first electrical conducting state in which a current is blocked or hardly flows in the selector layer 10 when the magnitude of the voltage supplied to the selector layer 10 is less than a predetermined threshold voltage, and a second electrical conducting state in which the current rapidly flows through the selector layer 10 at a voltage equal to or higher than the threshold voltage. This threshold value may be called a threshold voltage, and the selector 10 may be realized in a turn-on or turn-off state based on the threshold voltage. Because the selector layer 10 exhibits different electrical conducting characteristics in response to an applied voltage with respect to a threshold voltage and thus can be controlled via the applied voltage to be selected in one of the two different electrical conducting states, the selector layer 140 functions as a selector for selecting whether the memory cell embodying the selector layer 10 is selected or not.

The selector 10 according to the embodiment of the present disclosure may be used as a selector layer of a memory cell having a structure in which the selector layer and a memory layer are stacked in the upper and lower portions of a device. This will be described in more detail with reference to FIGS. 2A and 2B.

FIGS. 2A and 2B illustrate a semiconductor device in accordance with an embodiment of the present disclosure. As for the constituent elements of FIGS. 2A and 2B also appearing in FIGS. 1A to 1C, detailed description on them will be omitted in this embodiment.

Referring to FIGS. 2A and 2B, the semiconductor device according to the embodiment of the present disclosure may have a cross-point structure which includes a first conductive line 110 formed over a substrate 100 and extending in a first direction (D1), a second conductive line 130 disposed over the first conductive line 110 and extending in a second direction (D2) that perpendicular to the first direction (D1), and a memory cell 120 disposed at intersections between the first conductive line 110 and the second conductive line 130.

The substrate 100 may include a semiconductor material, for example, silicon. A lower structure (not shown) may be formed in the substrate 100. For example, the lower structure may include a driving circuit (not shown) that is electrically connected to control the first conductive line 110 and/or the second conductive line 130.

The first conductive line 110 and the second conductive line 130 may be coupled to the memory cell 120 and drive the memory cell 120 by transferring a voltage or current to the memory cell 120. One between the first conductive line 110 and the second conductive line 130 may be a word line, and the other may be a bit line. The first conductive line 110 and the second conductive line 130 may have a single-layer structure or a multi-layer structure including a conductive material. The conductive material may include at least one of metals, metal nitrides, conductive carbon materials, or combinations thereof. The conductive material is not limited to the example as described above and other implementations are also possible. For example, each of the first conductive line 110 and the second conductive line 130 may include tungsten (W), titanium (Ti), tantalum (Ta), platinum (Pt), aluminum (Al), copper (Cu), zinc (Zn), nickel (Ni), cobalt (Co), lead (Pd), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), carbon (C), silicon carbide (SIC), silicon carbon nitride (SiCN), or a combination thereof.

The memory cells 120 may be arranged in a matrix form in the first direction (D1) and the second direction (D2) to overlap with the intersection area of the first conductive line 110 and the second conductive line 130. The memory cell 120 may have a size that is equal to or smaller than the intersection area of the first conductive line 110 and the second conductive line 130, or a size that is greater than the intersection area.

The shape of the memory cell 120 may have a cylindrical pillar shape or a square pillar shape, but not limited thereto.

The space between the first conductive line 110, the second conductive line 130, and the memory cell 120 may be filled with a dielectric material (not shown).

The memory cell 120 may include a stacked structure, which includes a lower electrode 121, a selector pattern 122, a middle electrode 123, a memory pattern 124, and an upper electrode 125.

The selector pattern 122 shown in FIG. 2B may correspond to the selector 10 shown in FIG. 1C. Thus, the detailed description of the selector pattern 122, which is similar to the above-described embodiment of FIG. 1C, will be omitted.

The lower electrode 121 may be disposed in the lowermost portion of the memory cell 120, electrically connected to the first conductive line 110, and function as a transfer path for current or voltage between the first conductive line 110 and the memory cell 120. The middle electrode 123 may be disposed between the selector pattern 122 and the memory pattern 124, and may serve to electrically connect them to each other while physically separating them from each other. The upper electrode 125 may be disposed in the uppermost portion of the memory cell 120 and function as a transfer path for current or voltage between the second conductive line 130 and the memory cell 120.

The lower electrode 121, the middle electrode 123, and the upper electrode 125 may have a single-layer structure or a multi-layer structure including various conductive materials, such as a metal, a nitride, a silicide-based material, and a combination thereof. For example, the lower electrode 121, the middle electrode 123, and the upper electrode 125 may include tungsten (W), titanium (Ti), tantalum (Ta), platinum (Pt), aluminum (Al), copper (Cu), zinc (Zn), nickel (Ni), cobalt (Co), lead (Pd), chromium (Cr), tungsten nitride (WN), tungsten silicide (WSi), titanium silicide (TiSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), or a combination thereof.

The lower electrode 121, the middle electrode 123, and the upper electrode 125 may be formed of or include the same material or different materials.

The lower electrode 121, the middle electrode 123, and the upper electrode 125 may have the same thickness or different thicknesses.

At least one of the lower electrode 121, the middle electrode 123, or the upper electrode 125 may be selectively omitted. For example, when the lower electrode 121 is omitted, the first conductive line 110 may perform the function of the lower electrode 121 instead of the omitted lower electrode 121. When the upper electrode 125 is omitted, the second conductive line 130 may perform the function of the upper electrode 125 instead of the omitted upper electrode 125.

The selector pattern 122 may be a current adjustment layer which is configured to control current flow, and may prevent current leakage occurred between the memory cells 121 that share the first conductive line 110 or the second conductive line 130. The selector pattern 122 may have threshold switching characteristics by exhibiting two different electrical conducting states: a first electrical conducting state in which a current is blocked or hardly flows in the selector pattern 122 when the magnitude of the voltage supplied to the selector pattern 122 is less than a predetermined threshold voltage, and a second electrical conducting state in which the current rapidly flows through the selector pattern 122 at a voltage equal to or higher than the threshold voltage. This threshold value may be called a threshold voltage, and the selector pattern 122 may be realized in a turn-on or turn-off state based on the threshold voltage.

Unlike the conventional doped nitride or oxide-based selector, the selector pattern 122 may include amorphous carbon (C), which is the main component, and dopants, which are implanted through the ion implantation process, and may include a complex chemical bond which is formed by the chemical reaction between carbon (C) and the trivalent element. Also, the selector pattern 122 may optionally further include a chemical bond between at least one of nitrogen (N), oxygen (O), or hydrogen (H) and a trivalent element, in addition to the chemical bond between the carbon (C) and the trivalent element. The trivalent element may include at least one of boron (B), aluminum (Al), gallium (Ga), indium (In), or thallium (Tl), and the dopants may include at least one of arsenic (As), phosphorus (P), or antimony (Sb).

The selector pattern 122 may include carbon (C) of an amorphous phase, which may easily involve in a chemical reaction, as the main component, and may form a complex structural bond through a chemical reaction between carbon (C), which is a tetravalent element, and a trivalent element, thereby forming defects or vacancies in the selector pattern 122. Accordingly, the metallic states of the dopants may be maintained well, which make them possible to form trap sites of conductive carriers more easily and efficiently. This may further improve the electrical characteristics of the selector pattern 122. Also, the off-current characteristics may be controlled as the trivalent element which is chemically reacted with carbon traps some of the conductive carriers so as to prevent excessive current. Also, the physical characteristics of the selector pattern 122 may be improved due to the essential characteristics of carbon, which is the main component. When the selector pattern 122 further includes at least one of nitrogen (N), oxygen (O), or hydrogen (H) in addition to carbon (C), more complex structural bonds may be formed due to the chemical reaction between the additional element and the trivalent element, which may further increase the extent of forming defects or vacancies in the selector pattern 122. Therefore, it is possible to control the extent of the structural bond due to a chemical reaction in the selector pattern 122 by comprehensively considering the physical and electrical characteristics required for the target selector pattern 122.

The selector pattern 122 according to this embodiment of the present disclosure may have improved thickness, density, and flexibility, and may have reduced surface roughness, thereby exhibiting excellent electrical and physical characteristics. Also, the flatness of the selector pattern 122 is very important in order to contribute to stable crystallization of the memory pattern 122 when the memory pattern 124 is formed in the upper portion. The selector pattern 122 according to this embodiment of the present disclosure may have improved roughness characteristics due to the formation of complex structural bonds through a chemical reaction. Therefore, the memory pattern 124 may be crystallized more stably.

The memory pattern 124 may store different data by switching between different resistance states according to the voltage or current that is applied through the upper and lower portions. The memory pattern 124 may include a material used in a Resistive Random Access Memory (RRAM), a Phase-change Random Access Memory (PRAM), a Ferroelectric Random Access Memory (FRAM), a Magnetic Random Access Memory (MRAM), or others, for example, a material having variable resistance characteristics used in an RRAM, a PRAM, an FRAM, an MRAM, or others. The memory pattern 124 may include a transition metal oxide used in an RRAM, a PRAM, an FRAM, an MRAM or others, a metal oxide such as a perovskite-based material, a phase-change material such as a chalcogenide-based material, a ferroelectric material, a ferromagnetic material, or others.

For example, the memory pattern 124 may include a magnetic tunnel junction (MTJ) structure that includes a free layer with a changeable magnetization direction, a fixed layer with a fixed magnetization direction, and a tunnel barrier layer interposed between the free layer and the fixed layer.

The free layer may be a layer configured to store different data by having a changeable magnetization direction, and it may also be called a storage layer. The free layer may have one of different magnetization directions, or one of different electron spin directions, thereby switching the polarity of the free layer in the MTJ structure and changing the resistance value. According to some embodiments of the present disclosure, the polarity of the free layer may be changed or reversed when a voltage or current signal (e.g., a driving current which is equal to or higher than a predetermined threshold value) is applied to the MTJ structure. As the polarity of the free layer changes, the free layer and the fixed layer may have different magnetization directions or different electron spin directions. Therefore, the memory pattern 124 may store different data or represent different data bits. The magnetization direction of the free layer may vary between a top-down direction and a bottom-up direction. This change in the magnetization direction of the free layer may be induced by a spin transfer torque which is generated based on the applied current or voltage.

The fixed layer may have a fixed magnetization direction, which does not change while the magnetization direction of the free layer changes. The fixed layer may also be called a reference layer. According to some embodiments of the present disclosure, the fixed layer may be fixed to a magnetization direction from top to bottom. According to some embodiments of the present disclosure, the fixed layer may be fixed to a magnetization direction from bottom to top.

The free layer and the fixed layer may have a single-layer structure or a multi-layer structure including a ferromagnetic material. For example, the free layer and the fixed layer may include alloys including Fe, Ni or Co as the main component, such as Fe—Pt alloy, Fe—Pd alloy, Co—Pd alloy, Co—Pt alloy, Fe—Ni—Pt alloy, Co—Fe—Pt alloy, Co—Ni—Pt alloy, Co—Fe—B alloy, or others, or may include a stacked structure formed of metals, for example, a stacked structure such as Co/Pt, Co/Pd, or others.

The tunnel barrier layer may enable tunneling of electrons in both of a data read operation and a data write operation. The tunnel barrier layer may include a dielectric oxide, such as MgO, CaO, SrO, TiO, VO, NbO, Al₂O₃, TiO₂, Ta₂O₅, RuO₂, B₂O₃, or others.

The memory pattern 124 may have a single-layer structure or may have a multi-layer structure that exhibits variable resistance characteristics by combining two or more layers. However, the embodiment of the present disclosure is not limited thereto, and the memory cell 120 may include other memory layers that may store different data in various ways, instead of the memory pattern 124.

According to this embodiment of the present disclosure, the memory cell 120 may include the lower electrode 121, the selector pattern 122, the middle electrode 123, the memory pattern 124, and the upper electrode 125 that are sequentially stacked. However, the memory cell 120 may be modified variously as long as it has data storage characteristics. For example, at least one of the middle electrode 123 or the upper electrode 125 may be omitted. Also, the positions of the selector pattern 122 and the memory pattern 124 may be switched with each other. Also, the memory cell 120 may further include one or more layers (not shown) to improve the characteristics of the memory cell 120 in addition to the layers 121, 122, 123, 124 and 125 or to improve the process. For example, it may further include at least one of a lower electrode contact or an upper electrode contact. Also, for example, a hard mask pattern may remain.

The memory cells 120 formed as above may be disposed to be spaced apart from each other at regular intervals, and a trench may be formed between them. The trench between the memory cells 120 may have a height-to-width (H/W) aspect ratio in the range of, for example, approximately 1:1 to 40:1, or approximately 10:1 to 40:1, or approximately 10:1 to 20:1, or approximately 5:1 to 10:1, or approximately 10:1 to 15:1, or approximately 1:1 to 25:1, or approximately 1:1 to 30:1, or approximately 1:1 to 35:1, or 1:1 to 45:1, or approximately 1:1 to 40:1.

According to some embodiments of the present disclosure, these trenches may have sidewalls that are substantially perpendicular to the upper surface of the substrate 100. Also, according to one embodiment of the present disclosure, the neighboring trenches may be spaced apart from each other by substantially the same distance. However, according to another embodiment of the present disclosure, the space between the neighboring trenches may vary.

Although the cross-point structure having a single memory cell 120 is described in this embodiment of the present disclosure, the cross-point structure may include two or more memory cells 120 that are stacked in the vertical direction.

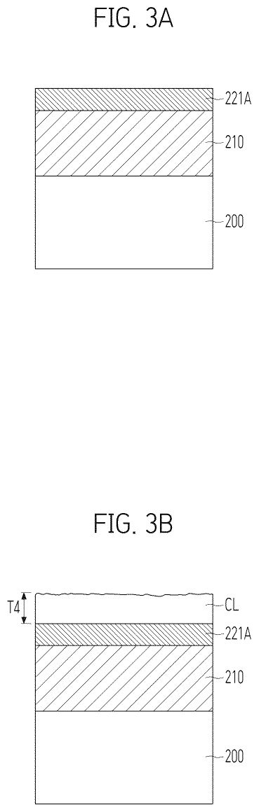

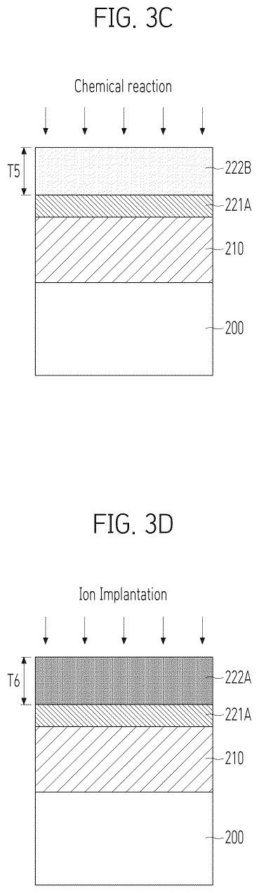

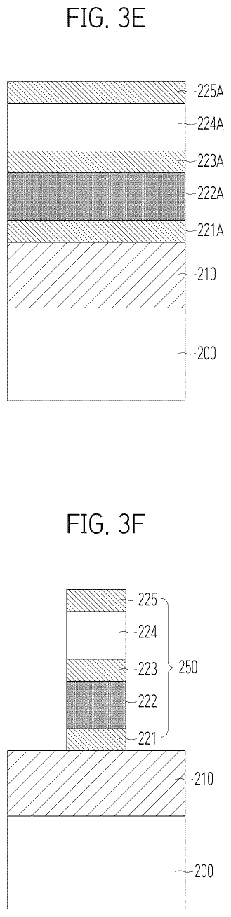

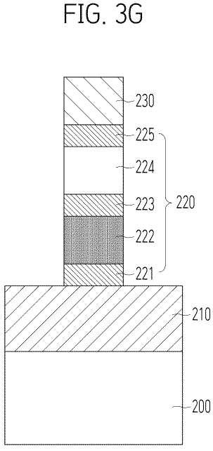

Subsequently, a method for fabricating a semiconductor device in accordance with the embodiment of the present disclosure will be described with reference to FIGS. 3A to 3G. In the following description, a lower electrode layer 221A, a selector layer 222A, a middle electrode layer 223A, a memory layer 224A, and an upper electrode layer 225A may represent material layers that are to be formed into a lower electrode 221, a selector pattern 222, a middle electrode 223, a memory pattern 224, and an upper electrode 225 through a patterning process, respectively.

Referring to FIG. 3A, a first conductive line 210 may be formed over a substrate 200 where a predetermined lower structure (not shown) is formed. The first conductive line 210 may be formed by forming a conductive layer for forming the first conductive line 210 over the substrate 200 and then etching the conductive layer using a line-shaped mask pattern that extends in the first direction (D1). The first conductive line 210 may have a single-layer structure or a multi-layer structure including a conductive material. Non-limiting examples of the conductive material may include metals, metal nitrides, conductive carbon materials, and combinations thereof.

A lower electrode layer 221A may be formed over the first conductive line 210. The lower electrode layer 221A may have a single-layer structure or a multi-layer structure including various conductive materials, such as a metal, a nitride, a silicide-based material, and a combination thereof.

Referring to FIG. 3B, a carbon layer CL may be formed over the lower electrode layer 221A.

The carbon layer CL may serve as a matrix forming the base of the selector. The carbon layer CL may be formed of an amorphous phase, which may easily involve in a chemical reaction, and when dopants such as arsenic (As) is ion-implanted, new structural bonds may be easily formed and the metallic states of the dopants may be maintained well. Since the ion-implanted dopant is configured to form the trap sites of the conductive carriers more easily and efficiently, the threshold switching operation characteristics of the selector may be effectively realized. Also, since the carbon layer CL has low density and high thermal conductivity, the selector based on the carbon layer CL may have excellent electrical and physical characteristics.

The carbon layer CL may be formed by depositing carbon (C) through a physical deposition method, for example, physical vapor deposition, e.g., sputtering method.

According to one embodiment of the present disclosure, the carbon layer CL may include carbon (C) atoms as the main component, and the carbon layer CL may further include at least one of nitrogen (N) atoms, oxygen (O) atoms, or hydrogen (H) atoms, in addition to carbon (C). In this case, the at least one of the nitrogen (N) atoms, oxygen (O) atoms, or hydrogen (H) atoms may be doped onto the carbon layer CL by performing the carbon (C) deposition process in the gas atmosphere of at least one of nitrogen gas, oxygen gas, or hydrogen gas.

The carbon layer CL may be formed to have a fourth thickness T4.

Referring to FIG. 3C, a chemical reaction may be performed onto the carbon layer CL to convert or modify the carbon layer CL into a chemical reaction layer 222B.

The chemical reaction shown in FIG. 3C may refer chemically reacting a trivalent element with the surface of the carbon layer CL. In other words, the trivalent element is not implanted into the carbon layer CL through a direct ion implantation process, but chemically reacts with the element included in the carbon layer CL. According to this embodiment of the present disclosure, through the chemical reaction shown in FIG. 3C, the chemical reaction layer 222B may include a complex chemical bond of the element included in the carbon layer CL and the trivalent element. As described above, the carbon layer CL may include carbon (C) atoms, and it may optionally further include at least one of nitrogen (N) atoms, oxygen (O) atoms, or hydrogen (H) atoms. Accordingly, the chemical reaction layer 222B may include carbon (C) as the main component and may include complex chemical bonds formed through the chemical reaction with the trivalent element. In other words, the chemical reaction layer 222B may include a chemical bond between carbon (C) and the trivalent element which is formed through the chemical reaction, and it may optionally include a chemical bond between at least one of nitrogen (N), oxygen (O), or hydrogen (H) and the trivalent element in addition to the chemical bond between the carbon (C) and the trivalent element.

The trivalent element may be able to control off-current characteristics by chemically reacting with the element included in the carbon layer CL to form a chemical bond and trapping some of the conductive carriers in the holes that are formed due to the trivalent structure to prevent excessive current.

The trivalent element configured to chemically react with the element included in the carbon layer CL may include at least one of boron (B), aluminum (Al), gallium (Ga), indium (In), or thallium (Tl).

In one embodiment of the present disclosure, when the trivalent element includes boron (B), the chemical reaction layer 222B may include a complex chemical bond formed of carbon (C), nitrogen (N), oxygen (O), hydrogen (H), or boron (B), for example, the chemical reaction layer 222B may include at least one of a B—C bond, a B—N bond, or a B—O bond.

The chemical reaction between the element included in the carbon layer CL and the trivalent element may be a plasma chemical reaction, and it may include a plasma doping (PLAD) process. When the trivalent element is chemically reacted with the carbon layer CL through the PLAD process, the trivalent element may chemically react with the elements including carbon (C) on the surface of and inside the carbon layer CL, forming new chemical bonds. As a result, it may be converted or modified into the chemical reaction layer 222B having a different structure and a different composition from those of the carbon layer CL.

According to one embodiment of the present disclosure, the chemical reaction between the element included in the carbon layer CL and the trivalent element may be performed through the PLAD process under the conditions of energy of approximately 1 to 5 KV and a trivalent element implantation amount of approximately 2.5×10¹⁵ to 2.5×10¹⁶ cm⁻². When the trivalent element implantation amount is out of the range, the flexibility of carbon that forms the base of the selector may be decreased. As a result, it may become difficult to secure stable physical characteristics of the selector.

According to one embodiment of the present disclosure, when the trivalent element includes boron (B), the PLAD process may be performed using B₂H₆ or BF₃ plasma. The PLAD process may be performed under the condition of energies of approximately 1 to 5 KV and the trivalent element implantation amount of approximately 2.5×10¹⁵ to 2.5×10¹⁶ cm⁻². Hydrogen (H) included in the B₂H₆ or BF₃ plasma used in the PLAD process may form a chemical bond in the chemical reaction layer 222B.

Since the chemical reaction layer 222B includes chemical bonds formed by the chemical reaction, a fifth thickness T5 of the chemical reaction layer 222B may be greater than the fourth thickness T4 of the carbon layer CL. In a dopant ion implantation process, which is a subsequent process when the selector pattern 222 is formed, the chemical reaction layer 222B may be damaged inevitably from the ion implantation process. Therefore, the chemical reaction layer 222B may have to secure the minimum thickness in order to function as a selector even though the chemical reaction layer 222B is damaged. According to this embodiment of the present disclosure, the fifth thickness T5 of the chemical reaction layer 222B may be increased to be greater than the fourth thickness T4 of the carbon layer CL before the conversion based on the chemical reaction with the trivalent element shown in FIG. 3B. Therefore, it is possible to secure stable physical characteristics of the selector pattern 222 which is finally formed despite the damage caused by the subsequent ion implantation process.

Also, the surface roughness characteristics of the chemical reaction layer 222B may be improved by the chemical reaction between the element included in the carbon layer CL and the trivalent element. Since the carbon layer CL is deposited by a method such as sputtering, the surface roughness may be poor. However, since the surface roughness of the chemical reaction layer 222B is reduced sufficiently due to the formation of the complex chemical bonds through the chemical reaction with the trivalent element, it may maintain the flat surface.

Also, the chemical reaction layer 222B may exhibit improved density and flexibility compared to the carbon layer CL due to the complex chemical bonds, and as a result, the physical characteristics of the selector pattern 222 may be improved.

Referring to FIG. 3D, dopants may be implanted into the chemical reaction layer 222B to form a selector layer 222A.

The dopants may form trap sites for conductive carriers, allowing the finally formed selector pattern 222 to perform a threshold switching operation.

The dopants may include, for example, at least one of arsenic (As), phosphorus (P), or antimony (Sb).

According to one embodiment of the present disclosure, the dopants may be implanted through an ion implantation process.

The selector layer 222A may be formed to have a sixth thickness T6. According to one embodiment of the present disclosure, the sixth thickness T6 of the selector layer 222A may be the same as the fifth thickness T5 of the chemical reaction layer 222B. According to another embodiment of the present disclosure, the sixth thickness T6 of the selector layer 222A may be smaller than the fifth thickness T5 of the chemical reaction layer 222B. This is because a portion of the upper portion of the chemical reaction layer 222B may be lost due to the damage that may occur during the ion implantation process.

Referring to FIG. 3E, a middle electrode layer 223A may be formed over the selector layer 222A. The middle electrode layer 223A may have a single-layer structure or a multi-layer structure including various conductive materials, such as a metal, a nitride, a silicide-based material, and a combination thereof.

A memory layer 224A may be formed over the middle electrode layer 223A. The memory layer 224A may be formed of a material that is used in an RRAM, a PRAM, an FRAM, an MRAM, or others, for example, a material having variable resistance characteristics used an RRAM, a PRAM, an FRAM, an MRAM, or others. According to one embodiment of the present disclosure, the memory layer 224A may include a transition metal oxide used in an RRAM, a PRAM, an FRAM, an MRAM, or others, a metal oxide such as a perovskite-based material, a phase-change material such as a chalcogenide-based material, a ferroelectric material, a ferromagnetic material, or others. According to another embodiment of the present disclosure, the memory layer 224A may have a magnetic tunnel junction (MTJ) structure that includes a free layer with a changeable magnetization direction, a fixed layer with a fixed magnetization direction, and a tunnel barrier layer interposed between the free layer and the fixed layer.

An upper electrode layer 225A may be formed over the memory layer 224A. The upper electrode layer 225A may have a single-layer structure or a multi-layer structure including various conductive materials, such as a metal, a nitride, a silicide-based material, and a combination thereof.

Referring to FIG. 3F, a memory cell 220 where a lower electrode 221, a selector pattern 222, a middle electrode 223, a memory pattern 224, and an upper electrode 225 are sequentially stacked may be formed by using a mask pattern as an etch mask and sequentially etching the upper electrode layer 225A, the memory layer 224A, the middle electrode layer 223A, the selector layer 222A, and the lower electrode layer 221A.

Referring to FIG. 3G, a second conductive line 230 may be formed over the upper electrode 225. The second conductive line 230 may be formed by depositing a conductive layer for forming the second conductive line 230 and etching the conductive layer with a line-shaped mask pattern extending in the second direction (D2).

Through the above process, the semiconductor device illustrated in FIG. 3G may be formed.

The semiconductor device according to this embodiment of the present disclosure may include the first conductive line 210, the memory cell 220, and the second conductive line 230 that are sequentially formed over the substrate 200. The memory cell 220 may include the lower electrode 221, the selector pattern 222, the middle electrode 223, the memory pattern 224, and the upper electrode 225 that are sequentially formed.

Unlike the conventional doped nitride or oxide selector, the selector pattern 222 may include amorphous carbon (C) which is the main component, and dopants which are ion-implanted, and the selector pattern 222 may include complex chemical bonds formed by a chemical reaction between carbon (C) and the trivalent element. Also, the selector pattern 222 may optionally further include a chemical bond between at least one of nitrogen (N), oxygen (O), or hydrogen (H) and the trivalent element, in addition to the chemical bond between the carbon (C) and the trivalent element. The trivalent element may include at least one of boron (B), aluminum (Al), gallium (Ga), indium (In), or thallium (Tl), while the dopants may include at least one of arsenic (As), phosphorus (P), or antimony (Sb).

The selector pattern 222 may include carbon (C) of an amorphous phase that may easily involve in a chemical reaction as the main component, and may form a complex structural bond through a chemical reaction between carbon (C), which is a tetravalent element, and the trivalent element, forming defects or vacancies in the selector pattern 222. Accordingly, the metallic states of the dopants may be maintained well, and the trap sites of conductive carriers may be formed more easily and efficiently. As a result, the electrical characteristics of the selector pattern 222 may be further improved. Also, the trivalent element chemically reacted with carbon may be able to prevent excessive current by trapping some of the conductive carriers. In this way, the off-current characteristics may be controlled. Also, the physical characteristics of the selector pattern 222 may be improved due to the essential characteristics of carbon, which is the main component. When the selector pattern 222 further includes at least one of nitrogen (N), oxygen (O), or hydrogen (H) in addition to carbon (C), more complex structural bonds may be formed through a chemical reaction between the additional element and the trivalent element, which may further increase the extent of forming defects or vacancies in the selector pattern 222. Therefore, the extent of the structural bonds due to the chemical reaction in the selector pattern 222 may be controlled by comprehensively considering the physical and electrical characteristics required for the target selector pattern 222.

The selector pattern 222 according to the embodiment of the present disclosure may have improved thickness, density, and flexibility, and may have reduced surface roughness, thereby exhibiting excellent electrical and physical characteristics. Also, the flatness of the selector pattern 222 is an important factor for stable crystallization of the memory pattern 222 when the memory pattern 124 in the upper portion is formed. Since the roughness characteristics of the selector pattern 222 according to this embodiment of the present disclosure is improved by forming complex structural bonds that are formed by a chemical reaction, the memory pattern 224 may be crystallized more stably.

The substrate 200, the first conductive line 210, the memory cell 220, the second conductive line 230, the lower electrode 221, the selector pattern 222, the middle electrode 223, the memory pattern 224, and the upper electrode 225 illustrated in FIG. 3G may respectively correspond to the substrate 100, the first conductive line 110, the memory cell 120, the second conductive line 130, the lower electrode 121, the selector pattern 122, the middle electrode 123, the memory pattern 124, and the upper electrode 125 illustrated in FIG. 2B.

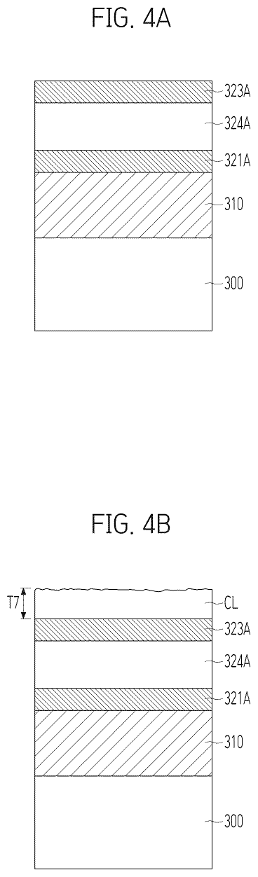

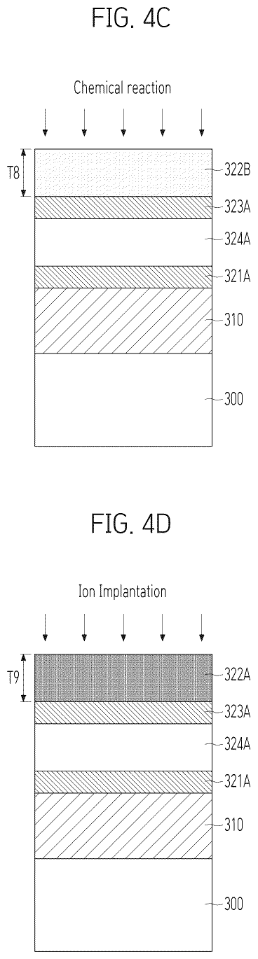

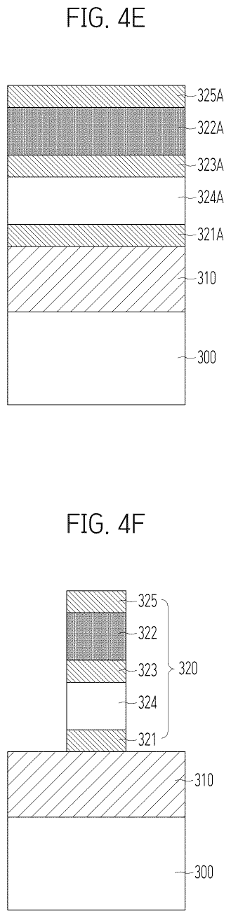

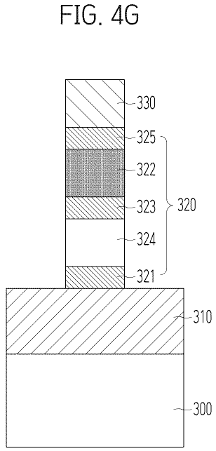

According to this embodiment of the present disclosure, the selector pattern 222 is formed below the memory pattern 224. However, the relative positions of the selector pattern 222 and the memory pattern 224 may be switched with each other. This will be described below with reference to FIGS. 4A to 4G.

FIGS. 4A to 4G illustrate a method for fabricating a semiconductor device in accordance with another embodiment of the present disclosure. The following description will focus on the differences from the embodiments illustrated in FIGS. 1A to 1C, 2A and 2B, and 3A to 3G. In the following description, a lower electrode layer 321A, a selector layer 322A, a middle electrode layer 323A, a memory layer 324A, and an upper electrode layer 325A may represent material layers that form a lower electrode 321, a selector pattern 322, a middle electrode 323, a memory pattern 324, and an upper electrode 325 through patterning processes.

Referring to FIG. 4A, a first conductive line 310 may be formed over a substrate 300 in which a predetermined lower structure (not shown) is formed. The first conductive line 310 may be formed by forming a conductive layer for forming the first conductive line 210 over the substrate 300 and then etching the conductive layer using a line-shaped mask pattern which extends in the first direction (D1).

The lower electrode layer 321A may be formed over the first conductive line 310. The lower electrode layer 321A may have a single-layer structure or a multi-layer structure including various conductive materials, such as a metal, a nitride, a silicide-based material, and a combination thereof.

The memory layer 324A may be formed over the lower electrode layer 321A. The memory layer 324A may be formed of a material used in an RRAM, a PRAM, an FRAM, an MRAM, or others, for example, a material having variable resistance characteristics used in an RRAM, a PRAM, an FRAM, an MRAM, or others.

The middle electrode layer 323A may be formed over the memory layer 324A. The middle electrode layer 323A may have a single-layer structure or a multi-layer structure including various conductive materials, such as a metal, a nitride, a silicide-based material, and a combination thereof.

Referring to FIG. 4B, a carbon layer CL may be formed over the middle electrode layer 323A. The carbon layer CL may be formed by depositing carbon (C) through a physical deposition method, for example, physical vapor deposition or sputtering.

According to one embodiment of the present disclosure, the carbon layer CL may include carbon (C) atoms as the main component, and the carbon layer CL may further include at least one of nitrogen (N) atoms, oxygen (O) atoms, or hydrogen (H) atoms in addition to carbon (C). In this case, the at least one of the nitrogen (N) atoms, oxygen (O) atoms, or hydrogen (H) atoms may be doped onto the carbon layer CL by performing a carbon (C) deposition process in a gas atmosphere of at least one of nitrogen gas, oxygen gas, or hydrogen gas.

The carbon layer CL may be formed to have a seventh thickness T7.

Referring to FIG. 4C, a chemical reaction may be performed onto the carbon layer CL to convert or modify the carbon layer CL into a chemical reaction layer 322B.

Through the chemical reaction shown in FIG. 4C, the chemical reaction layer 322B may include a complex chemical bond between the element included in the carbon layer CL and the trivalent element. In other words, the chemical reaction layer 322B may include a chemical bond between the carbon (C) formed by the chemical reaction and the trivalent element, and the chemical reaction layer 322B may optionally include a chemical bond between at least one of nitrogen (N), oxygen (O), or hydrogen (H) and the trivalent element in addition to the chemical bond between the carbon (C) formed by the chemical reaction and the trivalent element.

The trivalent element capable of chemically reacting with the element included in the carbon layer CL may include at least one of boron (B), aluminum (Al), gallium (Ga), indium (In), or thallium (Tl).

According to one embodiment of the present disclosure, when the trivalent element includes boron (B), the chemical reaction layer 322B may include a complex chemical bond formed of carbon (C), nitrogen (N), oxygen (O), hydrogen (H), or boron (B), for example, it may include at least one of a B—C bond, a B—N bond, or a B—O bond.

The chemical reaction between the element included in the carbon layer CL and the trivalent element may be a plasma chemical reaction and may include a plasma doping (PLAD) process. When the trivalent element is chemically reacted to the carbon layer CL through the PLAD process, the trivalent element may chemically react with the elements including carbon (C) on the surface of and inside the carbon layer CL, forming new chemical bonds. As a result, it may be converted or modified into the chemical reaction layer 222B having a different structure and a different composition from those of the carbon layer CL.

According to one embodiment of the present disclosure, the chemical reaction between the element included in the carbon layer CL and the trivalent element may be performed through the PLAD process under the conditions of energy of approximately 1 to 5 KV and a trivalent element implantation amount of approximately 2.5×10¹⁵ to 2.5×10¹⁶ cm⁻². When the trivalent element implantation amount is out of the above range, the flexibility of carbon that forms the base of the selector may be decreased, and as a result, it may be difficult to secure stable physical characteristics of the selector.

According to one embodiment of the present disclosure, when the trivalent element includes boron (B), the PLAD process may be performed using B₂H₆ or BF₃ plasma. The PLAD process may be performed under the conditions of energies of approximately 1 to 5 KV and a trivalent element implantation amount of approximately 2.5×10¹⁵ to 2.5×10¹⁶ cm⁻². Hydrogen (H) included in the B₂H₆ or BF₃ plasma that is used in the PLAD process may form a chemical bond in the chemical reaction layer 222B.

Since the chemical reaction layer 322B includes the chemical bond formed by the chemical reaction, an eighth thickness T8 of the chemical reaction layer 322B may be greater than the seventh thickness T7 of the carbon layer CL. This increase in the thickness may have a positive effect on securing stable physical characteristics of the finally formed selector pattern 322.

Also, the chemical reaction between the element included in the carbon layer CL and the trivalent element may improve the surface roughness characteristics of the chemical reaction layer 322B.

Also, the chemical reaction layer 322B may exhibit improved density and flexibility compared to the carbon layer CL due to the newly formed complex chemical bonds, and as a result, the physical characteristics of the selector pattern 322 may be improved.

Referring to FIG. 4D, dopants may be implanted into the chemical reaction layer 322B to form a selector layer 322A.

The dopants may form trap sites for conductive carriers, allowing the finally formed a selector pattern 322 to perform a threshold switching operation.

For example, the dopants may include at least one of arsenic (As), phosphorus (P), or antimony (Sb).

According to one embodiment of the present disclosure, the dopants may be implanted through an ion implantation process.

The selector layer 322A may be formed to have a ninth thickness T9. According to one embodiment of the present disclosure, the ninth thickness T9 of the selector layer 322A may be the same as the eighth thickness T8 of the chemical reaction layer 322B. According to another embodiment of the present disclosure, the thickness ninth T9 of the selector layer 322A may be smaller than the eighth thickness T8 of the chemical reaction layer 322B. This is because a portion of the upper portion of the chemical reaction layer 322B may be lost due to the damage that may occur during the ion implantation process.

Referring to FIG. 4E, an upper electrode layer 325A may be formed over the selector layer 322A. The upper electrode layer 323A may have a single-layer structure or a multi-layer structure including various conductive materials, such as a metal, a nitride, a silicide-based material, and a combination thereof.

Referring to FIG. 4F, the upper electrode layer 325A, the selector layer 322A, the middle electrode layer 323A, the memory layer 324A, and the lower electrode layer 321A may be sequentially etched by using the mask pattern as an etch mask. As a result, a memory cell 320 in which a lower electrode 321, a memory pattern 324, a middle electrode 323, a selector pattern 322, and an upper electrode 325 are sequentially stacked may be formed.

Referring to FIG. 4G, a second conductive line 330 may be formed over the upper electrode 325. The second conductive line 330 may be formed by depositing a conductive layer for forming the second conductive line 330 and etching the conductive layer using a line-shaped mask pattern which extends in the second direction (D2).

Through the above process, the semiconductor device shown in FIG. 4G may be formed.

The semiconductor device according to the embodiment of the present disclosure may include the first conductive line 310, the memory cell 320, and the second conductive line 330 that are sequentially formed over the substrate 300. The memory cell 320 may include the lower electrode 321, the memory pattern 324, the middle electrode 323, the selector pattern 322, and the upper electrode 325 that are formed sequentially.

Unlike conventional doped nitride or oxide selectors, the selector pattern 322 may include amorphous carbon (C) which is the main component and dopants which are ion-implanted, and the selector pattern 322 may include complex chemical bonds formed by a chemical reaction between carbon (C) and the trivalent element. Also, the selector pattern 322 may optionally further include a chemical bond between at least one of nitrogen (N), oxygen (O), or hydrogen (H) and the trivalent element in addition to the chemical bond between carbon (C) and the trivalent element. The trivalent element may include at least one of boron (B), aluminum (Al), gallium (Ga), indium (In), or thallium (Tl), while the dopants may include at least one of arsenic (As), phosphorus (P), or antimony (Sb).

The selector pattern 222 according to the embodiment of the present disclosure may have improved thickness, density, and flexibility, and may have reduced surface roughness, thereby exhibiting excellent electrical and physical characteristics.

The substrate 300, the first conductive line 310, the memory cell 320, the second conductive line 330, the lower electrode 321, the selector pattern 322, the middle electrode 323, the memory pattern 324, and the upper electrode 325 illustrated in FIG. 4G may be respectively correspond to the substrate 200, the first conductive line 210, the memory cell 220, the second conductive line 230, the lower electrode 221, the selector pattern 222, the middle electrode 223, the memory pattern 224 and the upper electrode 225 illustrated in FIG. 3G, and the substrate 100, the first conductive line 110, the memory cell 120, the second conductive line 130, the lower electrode 121, the selector pattern 122, the middle electrode 123, the memory pattern 124, and the upper electrode 125 illustrated in FIG. 2B.

According to the embodiment of the present disclosure, provided are a selector having excellent electrical and physical characteristics by using carbon as a matrix of the selector, chemically reacting the carbon with a trivalent element, and then ion-implanting dopants, a semiconductor device including the selector, and a method for fabricating the semiconductor device.

While the present disclosure has been described with respect to the specific embodiments, it will be apparent to those skilled in the art that various changes and modifications may be made without departing from the spirit and scope of the disclosure as defined in the following claims.

What is claimed is:

1. A selector comprising:
a carbon material that includes carbon and a trivalent element that is chemically bond to carbon; and
a dopant material implanted to the carbon material.

2. The selector of claim 1, wherein the dopant material implanted to the carbon material forms trap sites of conductive carriers based on a chemical bond between the carbon and the trivalent element in the carbon material.

3. The selector of claim 1, wherein the trivalent element includes at least one of boron (B), aluminum (Al), gallium (Ga), indium (In), or thallium (Tl).

4. The selector of claim 1, wherein the carbon material includes:
an additional element including at least one of nitrogen, oxygen, or hydrogen, wherein the additional element forms a chemical bond with the trivalent element.

5. The selector of claim 1, wherein the dopant material includes at least one of arsenic (As), phosphorus (P), or antimony (Sb).

6. The selector of claim 1, wherein a defect or vacancy is formed by a chemical bond between the trivalent element and the carbon.

7. The selector of claim 1, wherein the trivalent element includes boron (B), and the dopant material includes arsenic (As).

8. The selector of claim 1, wherein the carbon in the carbon material includes carbon in an amorphous phase.

9. A method for fabricating a selector comprising:
forming a carbon layer that includes carbon;
chemically reacting a trivalent element with the carbon in the carbon layer to chemically bond the trivalent element and the carbon; and
implanting a dopant through an ion implantation process.

10. The method of claim 9, wherein the dopant implanted to the carbon layer forms trap sites of conductive carriers based on a chemical bond between the carbon and the trivalent element in the carbon layer.

11. The method of claim 9, wherein the forming of the carbon layer includes performing a physical vapor deposition process.

12. The method of claim 9, wherein the forming of the carbon layer is performed in a gas atmosphere of at least one of nitrogen gas, oxygen gas, or hydrogen gas.

13. The method of claim 9, wherein the chemically reacting the trivalent element with the carbon layer includes reacting the trivalent element including at least one of boron (B), aluminum (Al), gallium (Ga), indium (In), or thallium (Tl).

14. The method of claim 9, wherein the chemically reacting the trivalent element with the carbon layer includes performing a plasma doping (PLAD) process.

15. The method of claim 14, wherein the PLAD process is performed using B₂H₆ or BF₃ plasma.

16. The method of claim 9, wherein a thickness of the carbon layer after the chemical reaction is greater than a thickness of the carbon layer before the chemical reaction.

17. The method of claim 9, wherein a surface roughness of the carbon layer after the chemical reaction is smaller than a surface roughness of the carbon layer before the chemical reaction.

18. The method of claim 9, wherein the ion implantation process is performed using a dopant including at least one of arsenic (As), phosphorus (P), or antimony (Sb).

19. A semiconductor device, comprising:
a selector pattern that includes carbon, a trivalent element and a dopant that are chemically bonded via a chemical bond among the carbon, the trivalent element, and the dopant; and
a memory pattern coupled to the selector pattern.

20. The semiconductor device of claim 19, wherein:
the carbon, the trivalent element, and the dopant that are chemically bonded to form trap sites of conductive carriers in the selector pattern to enable the selector pattern to exhibit different electrical conducting states in response to an applied voltage with respect to a threshold voltage, and
the memory pattern has an electrical connection with the selector pattern based on a state of the selector pattern in one of the different electrical conducting states.

21. The semiconductor device of claim 19, wherein:
the selector pattern is configured to control a flow of current and prevent current leakage between memory cells, and
the memory pattern is configured to store different data by switching between different resistance states according to an applied voltage or current.

22. The semiconductor device of claim 19, further comprising at least one of:
a first electrode disposed between the selector pattern and a substrate or between the substrate and the memory pattern;
a second electrode disposed between the selector pattern and the memory pattern; or
a third electrode disposed in an upper portion of the memory pattern or an upper portion of the selector pattern.

23. The semiconductor device of claim 19, wherein the trivalent element includes at least one of boron (B), aluminum (Al), gallium (Ga), indium (In), or thallium (Tl).

24. The semiconductor device of claim 19, wherein the selector pattern further includes a chemical bond between at least one of nitrogen, oxygen, or hydrogen and the trivalent element.

25. The semiconductor device of claim 19, wherein the dopant includes at least one of arsenic (As), phosphorus (P), or antimony (Sb).

26. The semiconductor device of claim 19 wherein a defect or vacancy is formed by the chemical bond in the selector pattern.

27. The semiconductor device of claim 19, wherein:
the trivalent element includes boron (B), and
the dopant includes arsenic (As).

28. The semiconductor device of claim 19, wherein the carbon has an amorphous phase.

29. A method for fabricating a semiconductor device, comprising:
forming a carbon layer containing carbon over a substrate;
performing a chemical reaction between a trivalent element and the carbon in the carbon layer to chemically bond the trivalent element and the carbon within the carbon layer;
subsequently implanting a dopant into the carbon layer through an ion implantation process to chemically bond the dopant with the trivalent element and the carbon;
forming a memory layer that is coupled to a selector layer; and
subsequently etching the memory layer and the selector layer using a mask pattern to form a memory pattern from the memory layer and a selector pattern from the carbon layer with the chemically bonded carbon, trivalent element and the dopant to form a memory cell including the memory pattern and the selector pattern.

30. The method of claim 29, further comprising at least one of:
forming a first electrode layer between the substrate and the selector layer or between the substrate and the memory layer;
forming a second electrode layer between the selector layer and the memory layer; or
forming a third electrode layer over the memory layer or over the selector layer.

31. The method of claim 29, wherein the forming of the carbon layer includes performing a physical vapor deposition process.

32. The method of claim 29, wherein the forming of the carbon layer is performed in a gas atmosphere of at least one of nitrogen gas, oxygen gas, or hydrogen gas.

33. The method of claim 29, wherein the chemically reacting the trivalent element with the carbon layer includes performing a reaction with a trivalent element including at least one of boron (B), aluminum (Al), gallium (Ga), indium (In), or thallium (Tl).

34. The method of claim 29, wherein the chemically reacting the trivalent element with the carbon layer includes performing a plasma doping (PLAD) process.

35. The method of claim 34, wherein the PLAD process is performed using B₂H₆ or BF₃ plasma.

36. The method of claim 29, wherein a thickness of the carbon layer after the chemical reaction is formed to be greater than a thickness of the carbon layer before the chemical reaction.

37. The method of claim 29, wherein a surface roughness of the carbon layer after the chemical reaction is formed to be smaller than a surface roughness of the carbon layer before the chemical reaction.

38. The method of claim 29, wherein the ion implantation process is performed using a dopant including at least one of arsenic (As), phosphorus (P), or antimony (Sb).
